(19) United States
(12) Patent Application Publication
(10) Pub. No.: US 2026/0160962 A1
(43) Pub. Date: Jun. 11, 2026

(54) METHOD FOR MANUFACTURING OPTOELECTRONIC MODULE

(71) Applicant: QuantumZ Inc., KAOHSIUNG CITY (TW)

(72) Inventors: MING-CHE HSIEH, KAOHSIUNG CITY (TW); PO-TING CHEN, KAOHSIUNG CITY (TW); SHIH-YU HUANG, KAOHSIUNG CITY (TW); HUNG-CHUN KENG, KAOHSIUNG CITY (TW); MENG-CEN CAI, KAOHSIUNG CITY (TW)

(21) Appl. No.: 19/233,126

(22) Filed: Jun. 10, 2025

(30) Foreign Application Priority Data
Dec. 11, 2024 (TW) 113148106

(51) Int. Cl. G02B 6/42; H01L 23/00

(52) U.S. Cl. CPC G02B 6/4245; H10W 72/075; H10W 90/754

(57) ABSTRACT

The invention relates to a method for manufacturing an optoelectronic module, including following steps: (1) preparing a first circuit substrate; (2) forming a first cladding layer on the first circuit substrate; (3) forming a core layer including a photosensitive material on the first cladding layer, and exposing the core layer by a light beam to form an optical channel; (4) preparing a second circuit substrate and a second cladding layer, arranging the second circuit substrate at a side of the core layer opposite to the first circuit substrate, and arranging the second cladding layer between the core layer and the second circuit substrate; (5) electrically connecting the first circuit substrate with the second circuit substrate by at least one conductive structure; and (6) mounting a plurality of optoelectronics to at least one of the first circuit substrate and the second circuit substrate.

### BACKGROUND OF THE INVENTION

### Field of the Invention

The present invention relates to a method for manufacturing an optoelectronic module.

### Description of the Prior Art

In conventional manufacturing processes for optoelectronic boards with optical waveguides, a cladding layer and a core layer are sequentially laminated or coated onto a circuit substrate. A photoresist is then applied to the core layer to form an exposure pattern. Through development, etching, and other processes, parts of the core layer are removed to form an optical channel. Finally, another cladding layer is laminated onto the core layer to complete the optical waveguide structure.

However, the aforementioned manufacturing process involves multiple complex steps, results in long production times, and incurs high manufacturing costs. Furthermore, in current exposure processes, the energy distribution of the laser beam follows a Gaussian profile, leading to poor edge sharpness of the exposure pattern. This, in turn, causes uneven edges in the optical channel, affecting the efficiency of light transmission. In addition, existing optoelectronic boards allow optoelectronic components to be placed on only one side, which limits their application and reduces signal transmission efficiency. Coupling among the optoelectronic components, optical channels, and copper traces also faces issues such as alignment difficulties, time-consuming, and poor optical coupling efficiency.

The present invention is, therefore, arisen to obviate or at least mitigate the above-mentioned disadvantages.

### SUMMARY OF THE INVENTION

The main object of the present invention is to provide a method for manufacturing an optoelectronic module through simplified processes, and the optoelectronic module enables high-speed signal transmission.

To achieve the above and other objects, the present invention provides a method for manufacturing an optoelectronic module, including following steps:
(1) preparing a first circuit substrate; (2) forming a first cladding layer on the first circuit substrate; (3) forming a core layer including a photosensitive material on the first cladding layer, and partially exposing the core layer by a light beam to form an optical channel; (4) preparing a second cladding layer and a second circuit substrate, arranging the second circuit substrate at a side of the core layer opposite to the first circuit substrate, and arranging the second cladding layer between the core layer and the second circuit substrate; (5) electrically connecting the first circuit substrate and the second circuit substrate by at least one conductive structure; and (6) mounting a plurality of optoelectronics to at least one of the first circuit substrate and the second circuit substrate.

The present invention will become more obvious from the following description when taken in connection with the accompanying drawings, which show, for purpose of illustrations only, the preferred embodiment(s) in accordance with the present invention.

### BRIEF DESCRIPTION OF THE DRAWINGS

FIGS. 1 to 7 are schematic diagrams showing steps of a first preferable embodiment of the present invention;

FIG. 8 is a partial top view of a core layer according to the first preferable embodiment of the present invention;

FIGS. 9 to 15 are schematic diagrams showing steps of a second preferable embodiment of the present invention;

FIGS. 16 to 22 are schematic diagrams showing steps of a third preferable embodiment of the present invention; and

FIGS. 23 to 29 are schematic diagrams showing steps of a fourth preferable embodiment of the present invention.

### DETAILED DESCRIPTION OF THE PREFERRED EMBODIMENTS

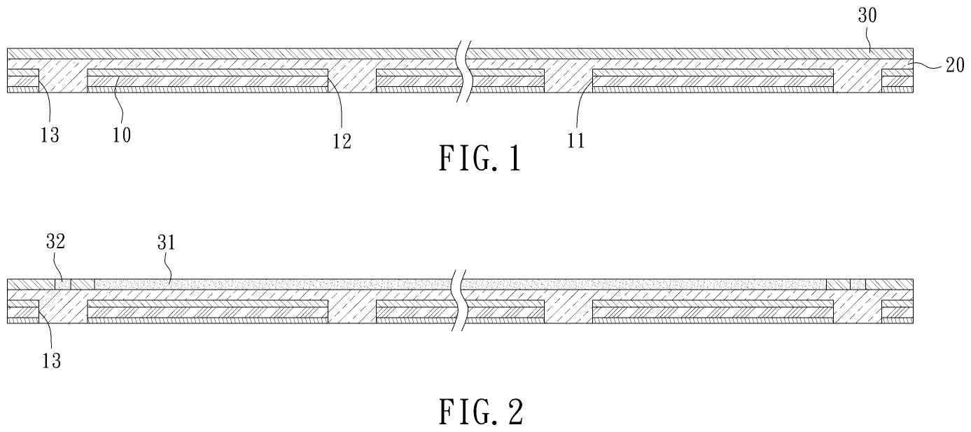

Please refer to FIGS. 1 to 8 for a first preferable embodiment of the present invention. A method for manufacturing an optoelectronic module 1 includes following steps.

Step (1): preparing a first circuit substrate 10. The first circuit substrate 10 may be a rigid printed circuit board (RPCB) or a flexible printed circuit (FPC), and may be selected as a single-sided, double-sided, or multi-layer board based on design requirements. The step (1) further includes forming a first optical opening 11 and a second optical opening 12 on the first circuit substrate 10.

Step (2): forming a first cladding layer 20 on the first circuit substrate 10. A cladding material may be coated onto the first circuit substrate 10 and filled into the first optical opening 11 and the second optical opening 12, and the cladding material is then cured by ultraviolet (UV) light or heat to form the first cladding layer 20. Alternatively, the cladding material may be pre-formed into a dry film, which is then laminated onto the first circuit substrate 10 to form the first cladding layer 20.

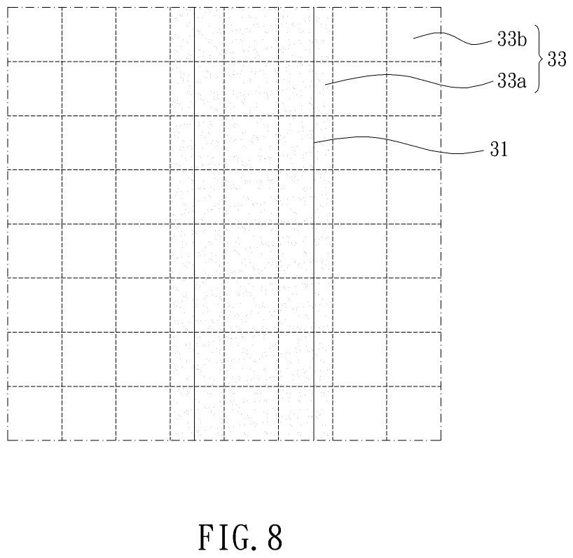

Step (3): providing a core layer 30 including a photosensitive material on the first cladding layer 20, and partially exposing the core layer 30 by a light beam to form an optical channel 31, as shown in FIGS. 1 and 2. The photosensitive material may include, but is not limited to, a positive-type dry film photoresist, a negative-type dry film photoresist, or other photosensitive films. Specifically, the step (3) further includes following steps: dividing the core layer 30 into a plurality of plurality of imaging units 33 arranged in a matrix (such as the areas surrounded by dash lines as shown in FIG. 8); providing an exposure pattern and determining each of the plurality of imaging units 33 as an exposed area 33a (such as the stippled areas as shown in FIG. 8) or a non-exposed area 33b according to the exposure pattern, as shown in FIG. 8; and irradiating at least a portion of said exposed areas 33a with the light beam to form the optical channel 31. Based on the photosensitive properties of the selected photosensitive material, a refractive index of each said exposed area 33a may be greater than a refractive index of each said non-exposed area 33b after exposure, in which case said exposed areas 33a form the optical channel 31; alternatively, the refractive index of each said exposed area 33a may be smaller than the refractive index of each said non-exposed area 33b, in which case said non-exposed areas 33b form the optical channel 31.

In this embodiment, a maskless exposure technique is employed. By adjusting a proportion of said exposed areas 33a irradiated by the light beam, a light dosage gradient at a boundary between said exposed and non-exposed areas 33a, 33b can be controlled, thereby enabling the optical channel 31 to have sharp edges formed through a single exposure process. For example, the light beam may be reflected to said exposed areas 33a via a digital micromirror device (DMD), such that 25%, 50%, 75%, or 100% of a total number of said exposed areas 33a are directly irradiated and exposed by the light beam, thereby acquiring a refractive index different from that of said non-exposed areas 33b. Each said exposed area 33a may be directly irradiated once or not directly irradiated, and said exposed areas 33a that are not directly irradiated may still be partially exposed due to the light energy diffused from adjacent exposed areas 33a that are directly irradiated. In this manner, the optical channel 31 can be directly formed after a baking process, without the need for photomasks, development, or etching steps, thereby saving time and reducing manufacturing costs while effectively enhancing the edge sharpness of the optical channel 31. Whether each exposed area is irradiated directly by the light beam may be determined randomly, manually, or according to a predefined rule. Preferably, at least one of the first cladding layer 20 and the first circuit substrate 10 includes a light-absorbing material, and the light-absorbing material is configured to absorb at least a portion of the light beam. For example, the light-absorbing material may absorb light with a specific wavelength, thereby reducing reflection of the light beam from the first cladding layer 20 or the first circuit substrate 10 back into the core layer 30 in the step (3), which helps to enhance the edge sharpness of the optical channel 31.

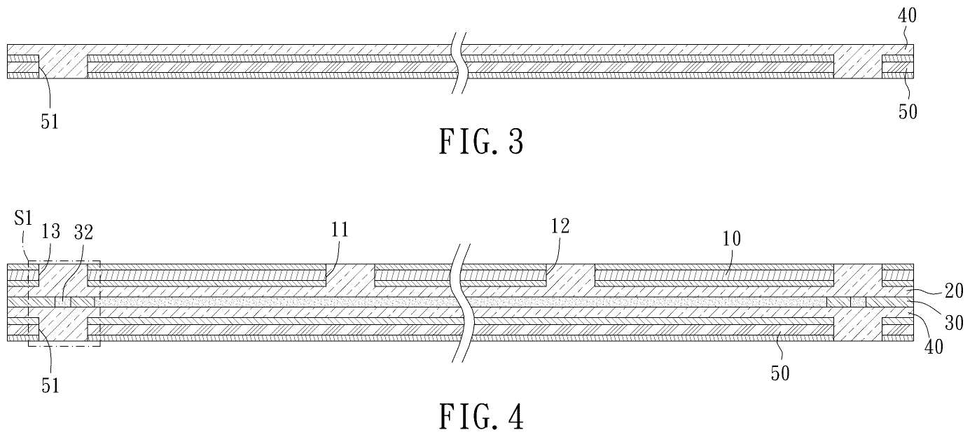

Step (4): preparing a second cladding layer 40 and a second circuit substrate 50, arranging the second circuit substrate 50 at a side of the core layer 30 opposite to the first circuit substrate 10, and arranging the second cladding layer 40 between the core layer 30 and the second circuit substrate 50. Similarly, the second circuit substrate 50 may be a rigid printed circuit board (RPCB) or a flexible printed circuit (FPC), and may be selected as a single-sided, double-sided, or multi-layer board based on design requirements. The second cladding layer 40 may first be bonded to the core layer 30, and the second circuit substrate 50 is then disposed on the second cladding layer 40. Alternatively, the second cladding layer 40 may first be bonded to the second circuit substrate 50, and then both are disposed together onto the core layer 30, as shown in FIGS. 3 and 4. Accordingly, the first cladding layer 20, the core layer 30 and the second cladding layer 40 not only serve to transmit optical signals, but also function as dielectric layers, thereby enabling the bonding between the first circuit substrate 10 and the second circuit substrate 50 without the need for additional adhesives, effectively simplifying the manufacturing steps and reducing manufacturing costs.

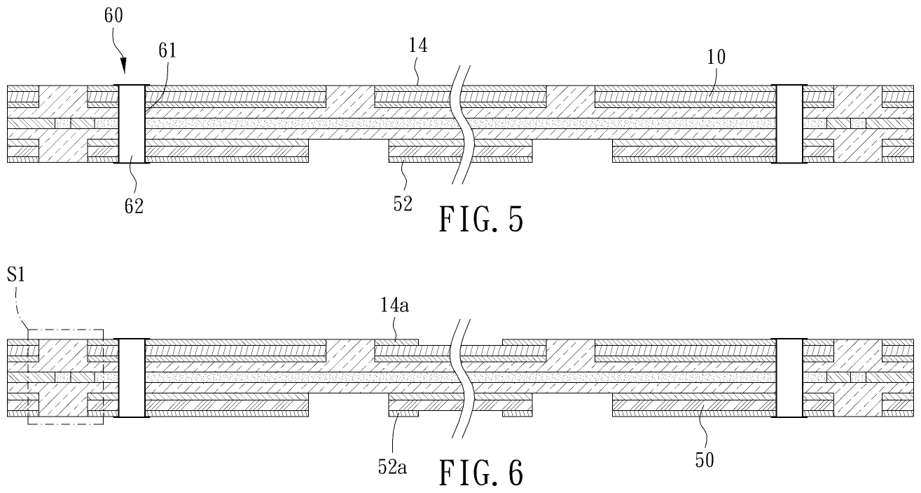

Step (5): electrically connecting the first circuit substrate 10 and the second circuit substrate 50 by at least one conductive structure 60, as shown in FIG. 5. The step (5) includes: forming at least one penetrating hole 61 extending though the first circuit substrate 10, the first cladding layer 20, the core layer 30, the second cladding layer 40 and the second circuit substrate 50, and forming an electrical conductor 62 penetrating through each of the at least one penetrating hole 61. Each said electrical conductor 62 may be a solid or hollow conductive pillar, a conductive coating, or the like, so as to establish electrical signal connection between the first circuit substrate 10 and the second circuit substrate 50.

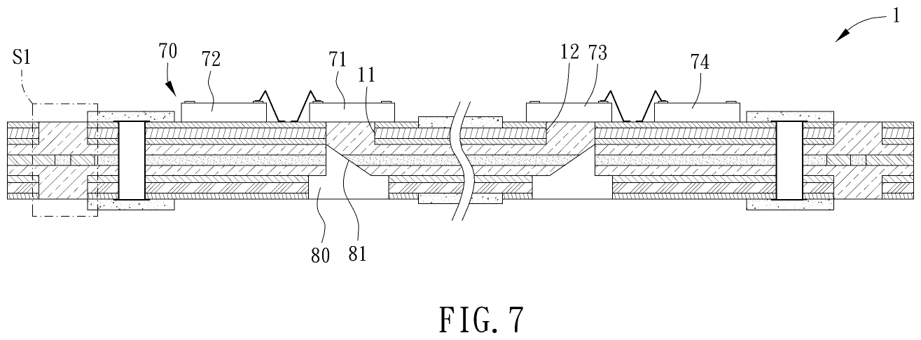

Step (6): mounting a plurality of optoelectronics 70 to at least one of the first circuit substrate 10 and the second circuit substrate 50, as shown in FIG. 7. In the step (6), two of the plurality of optoelectronics 70 are mounted to the first circuit substrate 10 and respectively correspond to the first optical opening 11 and the second optical opening 12. The plurality of optoelectronics 70 may include a top-emitting VCSEL, a bottom-emitting VCSEL, a control chip (such as driver IC), an optical receiver, a transimpedance amplifier (TIA), and other related components.

Moreover, after the step (5), the method further includes following steps: forming two recesses 80 extending toward the core layer 30 and two inclined surfaces 81 disposed within the two recesses 80 on the second circuit substrate 50, and forming a reflective surface on each of the two inclined surfaces 81. The two recesses 80 are located at a side of the second circuit substrate 50 and respectively opposite to the first optical opening 11 and the second optical opening 12. Each said reflective surface may be formed, for example, by coating a metal layer on one of the two inclined surfaces 81, such that optical signals can be transmitted between each of the plurality of optoelectronics 70 and the core layer 30.

By the aforementioned steps, the optoelectronic module 1 can be fabricated with a simplified and time-efficient process, while enabling high-speed signal transmission between the first circuit substrate 10 and the second circuit substrate 50, making it suitable for a wide range of applications. It should be particularly noted that the first circuit substrate 10 and the first cladding layer 20, as well as the second circuit substrate 50 and the second cladding layer 40, are not limited to being directly stacked in contact with each other; additional structures may be disposed therebetween as needed, allowing for an indirect stacked configuration.

Preferably, the step (1) further includes forming at least one first positioning hole 13 penetrating through the first circuit substrate 10. The step (3) further includes partially exposing the core layer 30 to form at least one positioning pattern 32 corresponding to the at least one first positioning hole 13. The step (4) further includes forming at least one second positioning hole 51 penetrating through the second circuit substrate 50 and corresponding to the at least one positioning pattern 32. In a thickness direction of the first circuit substrate 10, one said first positioning hole 13, one said positioning pattern 32 and one said second positioning hole 51 which are aligned with one another are defined as an optical target alignment reference S1. The first circuit substrate 10 and the second circuit substrate 50 each include a conductive layer 14,52, and before the step (6), said conductive layers 14,52 of the first circuit substrate 10 and the second circuit substrate 50 are etched according to the optical target alignment reference S1 to form a plurality of electrical contacts 14a,52a for connecting the plurality of optoelectronics 70. Since the positioning pattern 32 and the optical channel 31 are simultaneously formed in the same step, the optical target alignment reference S1 allows light to pass through and can serve as a positioning reference for forming the plurality of electrical contacts 14a,52a, thereby improving the alignment accuracy of the plurality of electrical contacts 14a,52a. In the step (6), at least one of the plurality of optoelectronics 70 is positioned according to the optical target alignment reference S1 so as to provide good optical coupling effect. In this embodiment, the plurality of optoelectronics 70 includes a bottom-emitting VCSEL 71 and a control chip 72. The bottom-emitting VCSEL 71 is aligned with the first optical opening 11 according to the optical target alignment reference S1 and mounted to the first circuit substrate 10, then electrically connected to the control chip 72 via wire bonding, which is easy to assembly. In other embodiments, the plurality of optoelectronics may include a top-emitting VCSEL, the top-emitting VCSEL may be aligned with the first optical opening according to the optical target alignment reference, and simultaneously aligned with the plurality of electrical contacts to be connected to the first circuit substrate via flip-chip bonding.

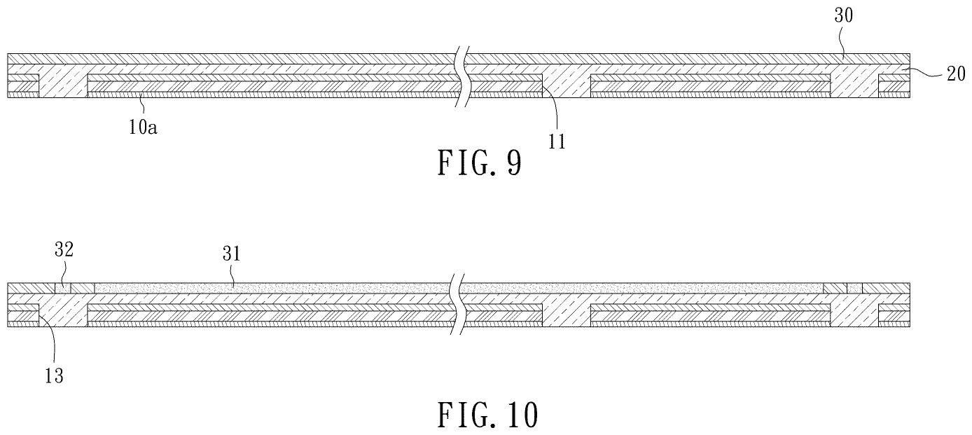

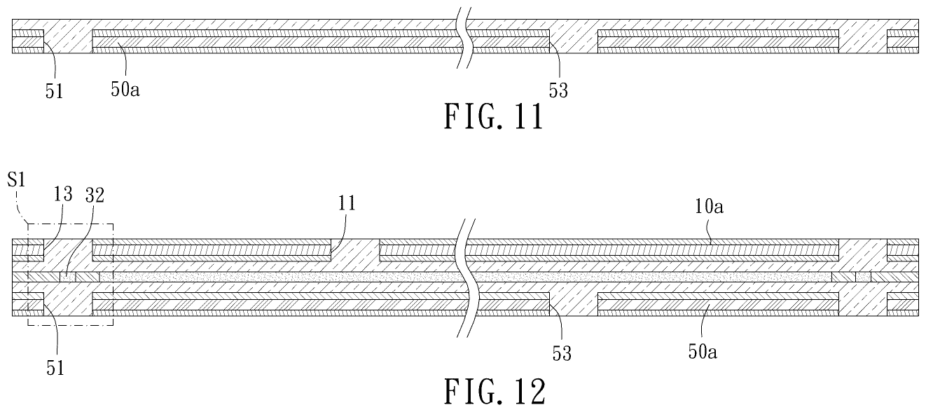

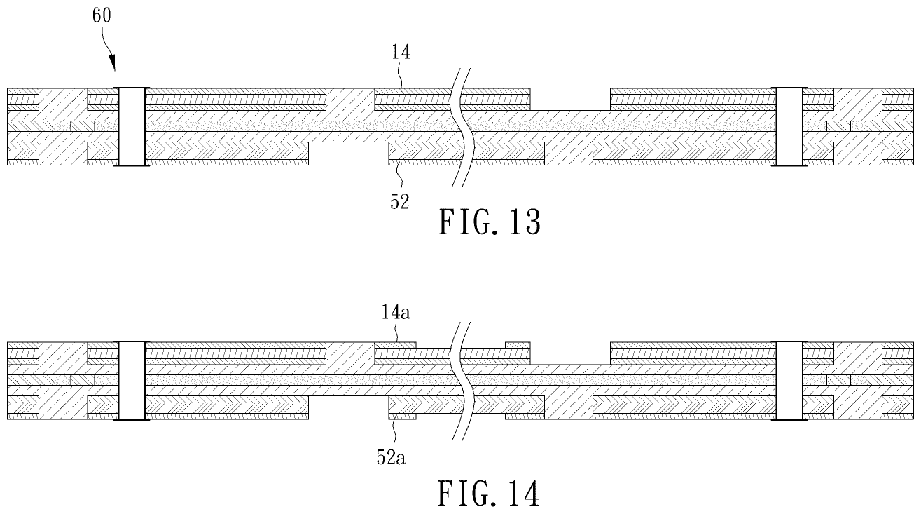

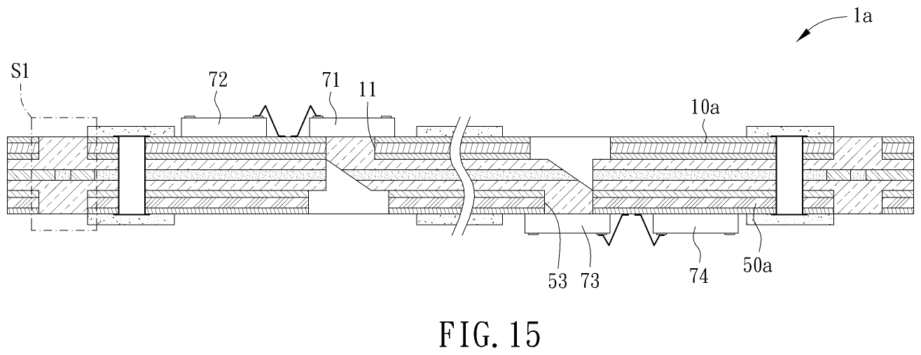

Referring to FIGS. 9 to 15, a second preferred embodiment of the present invention is illustrated. The difference between the second preferred embodiment and the first preferred embodiment lies in that: the plurality of optoelectronics 70 are respectively disposed on the first circuit substrate 10a and the second circuit substrate 50a. The step (1) further includes forming the first optical opening 11 on the first circuit substrate 10a. The step (4) further includes forming the second optical opening 53 on the second circuit substrate 50a. In the step (6), one of the plurality of optoelectronics 70 is aligned with the first optical opening 11 and mounted to the first circuit substrate 10a, and another one of the plurality of optoelectronics 70 is aligned with the second optical opening 53 and mounted to the second circuit substrate 50a. In this embodiment, the plurality of optoelectronics 70 include the bottom-emitting VCSEL 71, the control chip 72, an optical receiver 73 and a transimpedance amplifier 74. The bottom-emitting VCSEL 71 and the control chip 72 are mounted to the first circuit substrate 10a, and the optical receiver 73 and the transimpedance amplifier 74 are mounted to the second circuit substrate 50a, which allows optoelectronic signals to be transmitted between two opposite sides of the optoelectronic module 1a. In other embodiments, the plurality of optoelectronics may include other types of optical transmitters, optical receivers and associated components.

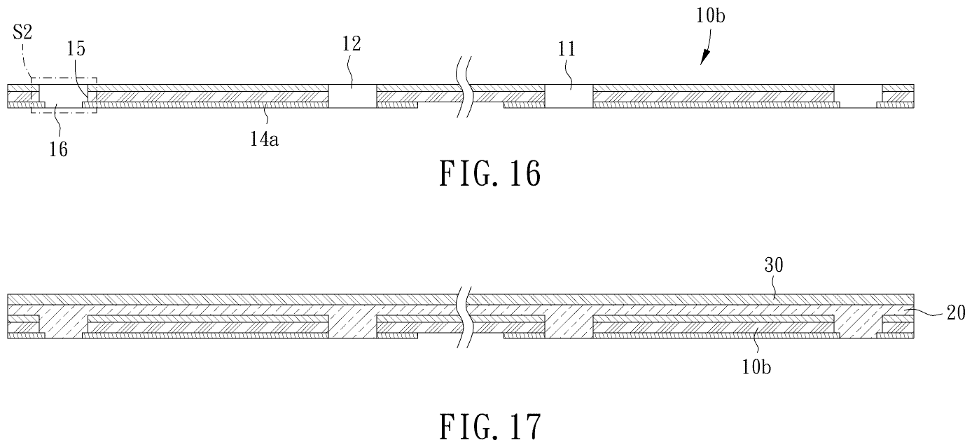

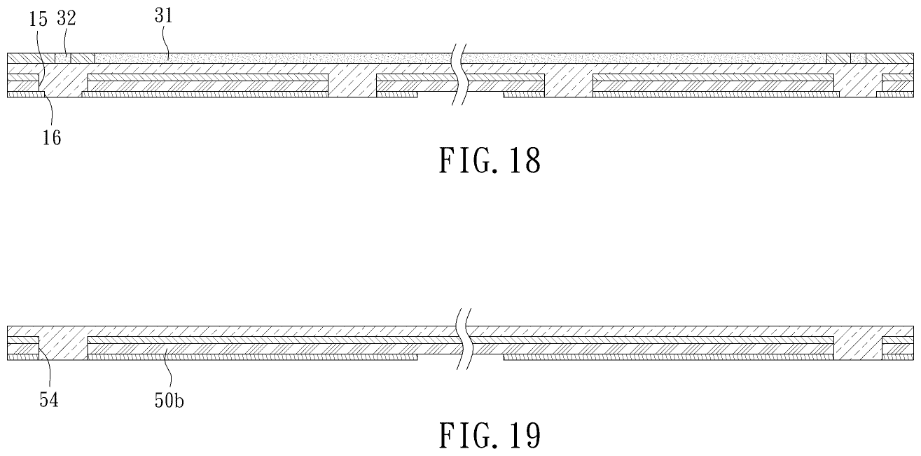

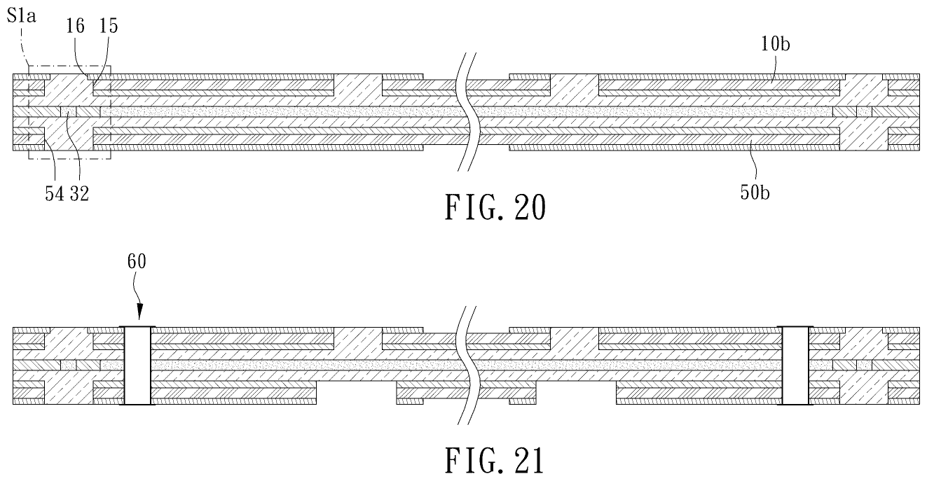

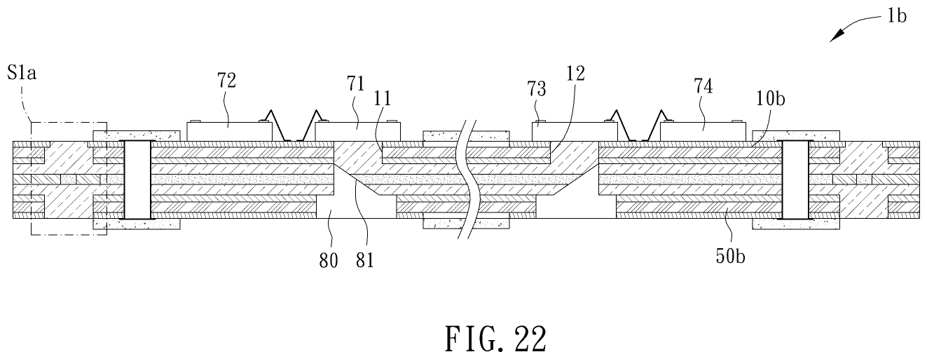

Referring to FIGS. 16 to 22, a third preferred embodiment of the present invention is illustrated. The difference between the third preferred embodiment and the first preferred embodiment lies in that: the step (1) further includes:
forming at least one third positioning hole 15 on a side of the first circuit substrate 10b opposite to the conductive layer 14, 52, and etching the conductive layer 14, 52 to form a plurality of electrical contacts 14a, 52a and at least one fourth positioning hole 16 communicated with the at least one third positioning hole 15. One said third positioning hole 15 and one said fourth positioning hole 16 which are communicated with each other have different diametrical dimensions and are defined as a substrate alignment reference S2. In the step (3), an irradiation area of the light beam is determined according to the substrate alignment reference S2, in other words, a position of the exposure pattern on the core layer 30 is determined according to the substrate alignment reference S2. Since the at least one fourth positioning hole 16 and the plurality of electrical contacts 14a, 52a are simultaneously formed in the same step, a hole wall of the at least one fourth positioning hole 16 can be seen when viewing the substrate alignment reference S2 in a thickness direction of one of the two conductive layer 14, 52. This allows the substrate alignment reference S2 to serve as a positioning reference for forming the optical channel 31, thereby enabling accurate alignment of the optical channel 31 with the plurality of electrical contacts 14a, 52a.

In this embodiment, the step (3) further includes partially exposing the core layer 30 to form at least one positioning pattern 32 corresponding to the substrate alignment reference S2. The step (4) further includes forming at least one fifth positioning hole 54 penetrating through the second circuit substrate 50b and corresponding to the at least one positioning pattern 32. In the thickness direction of the first circuit substrate 10b, one said third positioning hole 15, one said fourth positioning hole 16, one said positioning pattern 32 and one said fifth positioning hole 54 which are aligned with one another are defined as one said optical target alignment reference S1a. Therefore, in the step (6), the plurality of optoelectronics 70 can be positioned according to the optical target alignment reference S1a for good optical coupling effect. In other embodiments, each said substrate alignment reference may be misaligned with one said optical target alignment reference as described in the first preferable embodiment; the optoelectronic module may be provided with only said optical target alignment reference or only said substrate alignment reference.

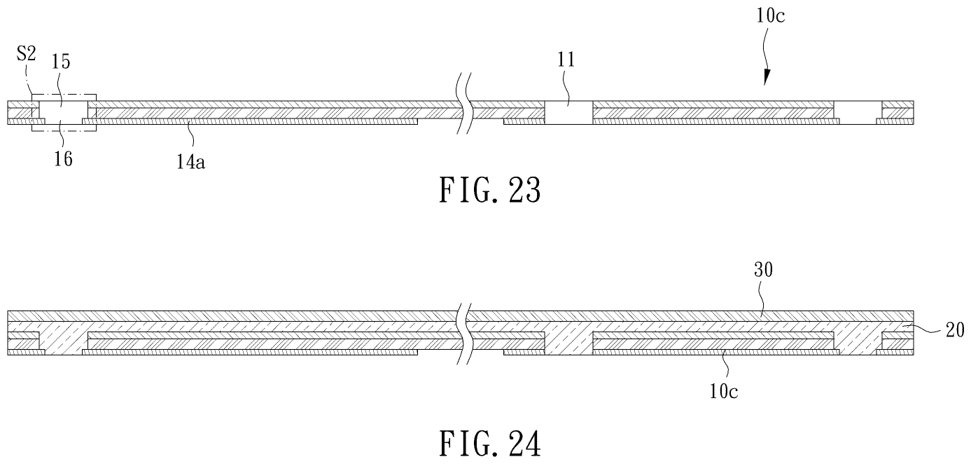

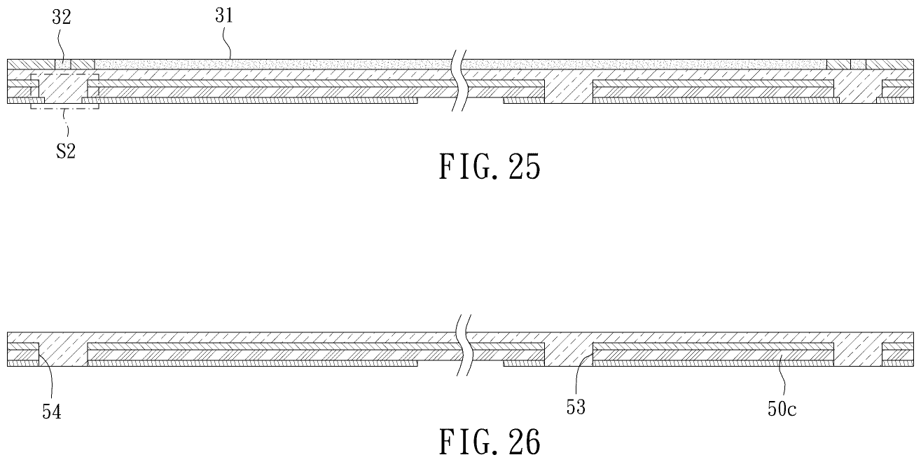

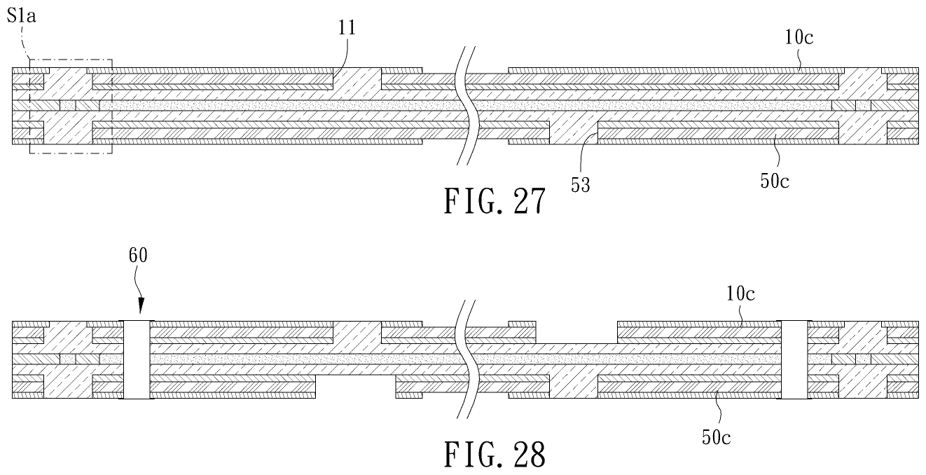

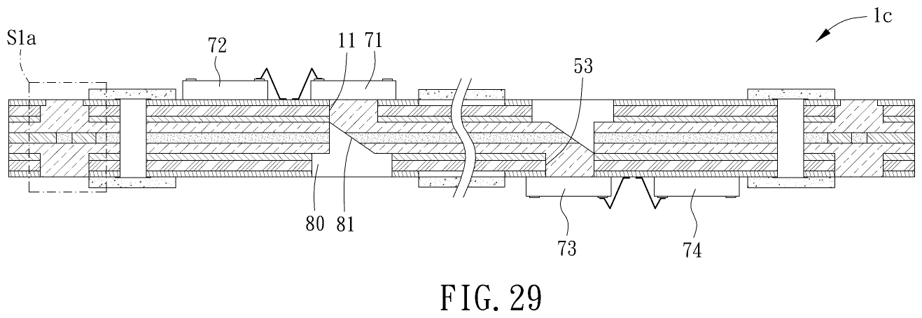

Referring to FIGS. 23 to 29, a fourth preferred embodiment of the present invention is illustrated. The difference between the fourth preferred embodiment and the third preferred embodiment lies in that: the plurality of optoelectronics 70 are respectively disposed on the first circuit substrate 10c and the second circuit substrate 50c. Similar to the second preferred embodiment, optoelectronic signals can be transmitted between two opposite sides of the optoelectronic module 1c.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A method for manufacturing an optoelectronic module, including following steps:
(1) preparing a first circuit substrate;
(2) forming a first cladding layer on the first circuit substrate;
(3) forming a core layer including a photosensitive material on the first cladding layer, and partially exposing the core layer by a light beam to form an optical channel;
(4) preparing a second cladding layer and a second circuit substrate, arranging the second circuit substrate at a side of the core layer opposite to the first circuit substrate, and arranging the second cladding layer between the core layer and the second circuit substrate;
(5) electrically connecting the first circuit substrate and the second circuit substrate by at least one conductive structure; and
(6) mounting a plurality of optoelectronics to at least one of the first circuit substrate and the second circuit substrate.

2. The method for manufacturing the optoelectronic module of claim 1, wherein the step (1) further includes forming a first optical opening and a second optical opening on the first circuit substrate; and in the step (6), two of the plurality of optoelectronics are respectively aligned with the first optical opening and the second optical opening and mounted to the first circuit substrate.

3. The method for manufacturing the optoelectronic module of claim 1, wherein the step (1) further includes forming a first optical opening on the first circuit substrate; the step (4) further includes forming a second optical opening on the second circuit substrate; in the step (6), one of the plurality of optoelectronics is aligned with the first optical opening and mounted to the first circuit substrate, and another one of the plurality of optoelectronics is aligned with the second optical opening and mounted to the second circuit substrate.

4. The method for manufacturing the optoelectronic module of claim 2, further including following steps: forming two recesses extending toward the core layer and two inclined surfaces disposed within the two recesses on the second circuit substrate, and forming a reflective surface on each of the two inclined surfaces, wherein the two recesses are located at a side of the second circuit substrate and respectively opposite to the first optical opening and the second optical opening.

5. The method for manufacturing the optoelectronic module of claim 3, further including following steps: forming two recesses extending toward the core layer and two inclined surfaces disposed within the two recesses, and forming a reflective surface on each of the two inclined surfaces, wherein one of the two recesses is located at a side of the first circuit substrate opposite to the first optical opening, and the other of the two recesses is located at a side of the second circuit substrate opposite to the second optical opening.

6. The method for manufacturing the optoelectronic module of claim 1, wherein the step (5) includes: forming at least one penetrating hole extending though the first circuit substrate, the first cladding layer, the core layer, the second cladding layer and the second circuit substrate, and forming an electrical conductor penetrating through each of the at least one penetrating hole.

7. The method for manufacturing the optoelectronic module of claim 1, wherein the step (3) further includes: dividing the core layer into a plurality of imaging units arranged in a matrix; providing an exposure pattern and determining each of the plurality of imaging units as an exposed area or a non-exposed area according to the exposure pattern;
and irradiating at least a portion of said exposed areas with the light beam to form the optical channel.

8. The method for manufacturing the optoelectronic module of claim 7, wherein after the step (3), a refractive index of each said exposed area is greater than a refractive index of each said non-exposed area, and said exposed areas form the optical channel.

9. The method for manufacturing the optoelectronic module of claim 7, wherein after the step (3), a refractive index of each said exposed area is smaller than a refractive index of each said non-exposed area, and said non-exposed areas form the optical channel.

10. The method for manufacturing the optoelectronic module of claim 1, wherein at least one of the first cladding layer and the first circuit substrate includes a light-absorbing material, and the light-absorbing material is configured to absorb at least a portion of the light beam.

11. The method for manufacturing the optoelectronic module of claim 1, wherein the step (1) further includes forming at least one first positioning hole penetrating through the first circuit substrate; the step (3) further includes partially exposing the core layer to form at least one positioning pattern corresponding to the at least one first positioning hole; the step (4) further includes forming at least one second positioning hole penetrating through the second circuit substrate and corresponding to the at least one positioning pattern, and in a thickness direction of the first circuit substrate, one said first positioning hole, one said positioning pattern and one said second positioning hole which are aligned with one another are defined as an optical target alignment reference.

12. The method for manufacturing the optoelectronic module of claim 11, wherein the first circuit substrate and the second circuit substrate each include a conductive layer, and before the step (6), said conductive layers of the first circuit substrate and the second circuit substrate are etched according to the optical target alignment reference to form a plurality of electrical contacts for connecting the plurality of optoelectronics.

13. The method for manufacturing the optoelectronic module of claim 11, wherein in the step (6), at least one of the plurality of optoelectronics is positioned according to the optical target alignment reference.

14. The method for manufacturing the optoelectronic module of claim 1, wherein the first circuit substrate includes a conductive layer, the step (1) further includes: forming at least one third positioning hole on a side of the first circuit substrate opposite to the conductive layer, and etching the conductive layer to form a plurality of electrical contacts and at least one fourth positioning hole communicated with the at least one third positioning hole, and one said third positioning hole and one said fourth positioning hole which are communicated with each other have different diametrical dimensions and are defined as a substrate alignment reference.

15. The method for manufacturing the optoelectronic module of claim 14, wherein in the step (3), an irradiation area of the light beam is determined according to the substrate alignment reference.

16. The method for manufacturing the optoelectronic module of claim 14, wherein the step (3) further includes exposing the core layer to form at least one positioning pattern corresponding to the substrate alignment reference; the step (4) further includes forming at least one fifth positioning hole penetrating through the second circuit substrate and corresponding to the at least one positioning pattern, in a thickness direction of the first circuit substrate, one said third positioning hole, one said fourth positioning hole, one said positioning pattern and one said fifth positioning hole which are aligned with one another are defined as an optical target alignment reference.
